(19) United States
(12) Patent Application Publication
(10) Pub. No.: US 2026/0096055 A1
(43) Pub. Date: Apr. 2, 2026

(54) LIQUID COOLING STRUCTURE AND ELECTRONIC DEVICE USING THE SAME

(71) Applicant: ACBEL POLYTECH INC., New Taipei City (TW)

(72) Inventors: Chien-Ting CHO, New Taipei City (TW); Shih-Cheng SUN, New Taipei City (TW); I-Chun CHENG, New Taipei City (TW)

(73) Assignee: ACBEL POLYTECH INC., New Taipei City (TW)

(21) Appl. No.: 18/901,155

(22) Filed: Sep. 30, 2024

(51) Int. Cl. H05K 7/20; H05K 1/02

(52) U.S. Cl. CPC H05K 7/20254; H05K 1/0203; H05K 7/20272; H05K 7/2039

(57) ABSTRACT

A liquid cooling structure for being used in an electronic device is configured to wrap a heat-generating component and has a cooling plate and a circuit board. The cooling plate and the circuit board is arranged to form a space for accommodating the heat-generating component. The space is filled with a first thermal conductive medium, which is in direct contact with the cooling plate, the circuit board and the heat-generating component. A structure and assembling processes of the liquid cooling structure are simplified. Accordingly, sizes of the liquid cooling structure and the electronic device having the liquid cooling structure are also reduced.

### BACKGROUND OF THE INVENTION

### 1. Field of the Invention

The present invention relates to a liquid cooling structure, especially to a liquid cooling structure used in electronic devices.

### 2. Description of the Prior Art(s)

As technology continuous to develop around the world, heat output of high-performance chips, serves and power supplies required to support various innovative technologies is also increasing. In order to improve heat dissipation efficiency to ensure normal operation of the hardware and extend service life of the equipment, liquid cooling techniques have gradually replaced traditional air cooling techniques.

With reference to FIG. 5, take a power supply as an example, a conventional liquid cooling structure wraps a main heat-generating component, a transformer module 51, inside a heat sink 52. The heat sink 52 may be an aluminum heat sink made of aluminum or aluminum alloy. A first thermal conductive medium 53 is filled between the transformer module 51 and the heat sink 52. An aluminum substrate 54 provided with power semiconductors 541 and a cooling plate 55 provided with a cooling liquid flow channel 551 are attached to an outer sidewall of the heat sink 52 with a second thermal conductive medium 56. The first thermal conductive medium 53 is able to reduce thermal resistance between the heat sink 52 and the transformer module 51. The second thermal conductive medium 56 is able to reduce thermal resistances between the heat sink 52 and the aluminum substrate 54 and between the heat sink 52 and the cooling plate 55. Thus, heat generated during operation of the transformer module 51 and the power semiconductors 541 is able to be conducted to cooling liquid flowing in the cooling plate 55 and then be dissipated.

However, the problem of the conventional liquid cooling structure is that the heat sink 52 is large in size, which consequently leads to the overall liquid cooling structure and the power supply being bulky and unable to be further reduced in size. The multiple thermal resistances formed by the first thermal conductive medium 53, the heat sink 52, the second thermal conductive medium 56, and the cooling plate 55 also result in poor thermal conductivity. Moreover, the conventional liquid cooling structure including the heat sink 52 also face the issue of having a complex assembly processes with many steps.

### SUMMARY OF THE INVENTION

To overcome the shortcomings, the present invention provides a liquid cooling structure and an electronic device using the same to mitigate or obviate the aforementioned problems.

One of the main objectives of the present invention is to provide a liquid cooling structure and an electronic device using the liquid cooling structure. The liquid cooling structure is configured to wrap a heat-generating component and has a cooling plate and a circuit board. The cooling plate and the circuit board are arranged to form a space for accommodating the heat-generating component. The space is filled with a first thermal conductive medium. The first thermal conductive medium is in direct contact with the cooling plate and is in direct contact with the circuit board.

Further, the liquid cooling structure comprises a flow channel formed in the cooling plate for cooling liquid to flow through.

Further, the circuit board is mounted with at least one additional heat-generating component.

Further, the at least one additional heat-generating component is mounted on an outer surface of the circuit board.

Further, the circuit board is mounted with a plurality of said at least one additional heat-generating components, and the additional heat-generating components are respectively mounted on an outer surface and an inner surface of the circuit board.

Further, the cooling plate has at least one fastening protrusion formed on an outer sidewall of the cooling plate.

Further, the liquid cooling structure further comprises a fastener fastened, passing through the circuit board, to a corresponding one of the at least one fastening protrusion.

Further, the liquid cooling structure comprises a connector having a portion fastened to the cooling plate and another portion fastened to the circuit board. The cooling plate and the circuit board are connected with each other through the connector.

Further, the liquid cooling structure comprises a fastener fastened, passing through the connector, to the cooling plate.

Further, the liquid cooling structure comprises a thermal block mounted on an outer sidewall of the cooling plate. The portion of the cooling plate with the thermal block, together with the circuit board, forms the space for accommodating the heat-generating component, so that the cooling plate is in contact with the first thermal conductive medium through the thermal block.

Further, the thermal block is attached to the cooling plate through a second thermal conductive medium.

Another main objective of the present invention is to provide an electronic device comprising a first heat-generating component and a liquid cooling structure wrapping the first heat-generating component. The liquid cooling structure comprises: a cooling plate having two sidewalls to form a flow channel for cooling liquid to flow through; and a circuit board having two substrates fastened to one of the sidewalls of the cooling plate. The cooling plate and the substrates form a space for accommodating the first heat-generating component, and the space is filled with a first thermal conductive medium. The first thermal conductive medium is in direct contact with the cooling plate and is in direct contact with the circuit board.

Further, each of the substrates has an inner surface and an outer surface, and the electronic device further comprises at least one second heat-generating component mounted on at least one of the outer and inner surfaces of the substrates.

Further, the cooling plate has a plurality of fastening protrusions formed on an outer surface of one of the sidewalls of the cooling plate, and the liquid cooling structure further comprises a plurality of fasteners respectively fastened to the fastening protrusions through the substrates.

Further, the liquid cooling structure further comprises: a plurality of connectors, and each of the connectors having a portion fastened to the cooling plate and another portion fastened to the circuit board; and a plurality of fasteners respectively fastened to an outer surface of one of the sidewalls of the cooling plate through the connectors.

Further, a minimum thermal resistance between the first heat-generating component and the cooling plate is consisting of the first thermal conductive medium.

The other main objective of the present invention is to provide an electronic device comprising a first heat-generating component and a liquid cooling structure wrapping the first heat-generating component.

The liquid cooling structure comprises: a cooling plate having two sidewalls to form a flow channel for cooling liquid to flow through; a circuit board having two substrates fastened to one of the sidewalls of the cooling plate; and a thermal block mounted on one of the sidewalls, to which the two substrates of the circuit board is fastened, of the cooling plate. The thermal block and the substrates form a space for accommodating the first heat-generating component, and the space is filled with a first thermal conductive medium. The first thermal conductive medium is thermal contact with the cooling plate through the thermal block and is in direct contact with the circuit board.

Further, the thermal block is attached to the cooling plate through a second thermal conductive medium.

Further, a minimum thermal resistance between the first heat-generating component and the circuit board is consisting of the first thermal conductive medium.

Further, the thermal block is in direct contact with only a portion of an inner surface of each of the substrates of the circuit board.

In the liquid cooling structure, the first thermal conductive medium is in direct contact with the heat-generating component, the circuit board and the cooling plate. Therefore, in addition to simplifying a structure and assembling processes of the liquid cooling structure, thermal resistances in the liquid cooling structure can be reduced and thermal conductivity of the liquid cooling structure can be improved. Moreover, a size of the liquid cooling structure and a size of the electronic device having the liquid cooling structure can also be further reduced.

### BRIEF DESCRIPTION OF THE DRAWINGS

FIG. 1 is a schematic side view of a first embodiment of a liquid cooling structure in accordance with the present invention;

FIG. 2 is a schematic side view of a second embodiment of a liquid cooling structure in accordance with the present invention;

FIG. 3 is a schematic side view of a third embodiment of a liquid cooling structure in accordance with the present invention;

FIG. 4 is a schematic side view of a fourth embodiment of a liquid cooling structure in accordance with the present invention; and

FIG. 5 is a schematic side view of a liquid cooling structure in accordance with the prior art.

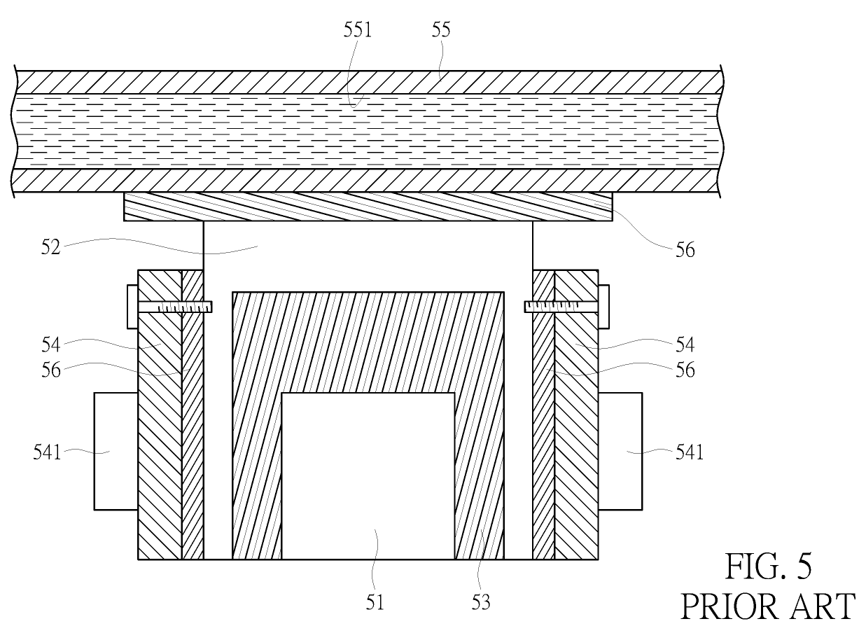

### DETAILED DESCRIPTION OF THE PREFERRED EMBODIMENTS

Other objectives, advantages and novel features of the invention will become more apparent from the following detailed description when taken in conjunction with the accompanying drawings.

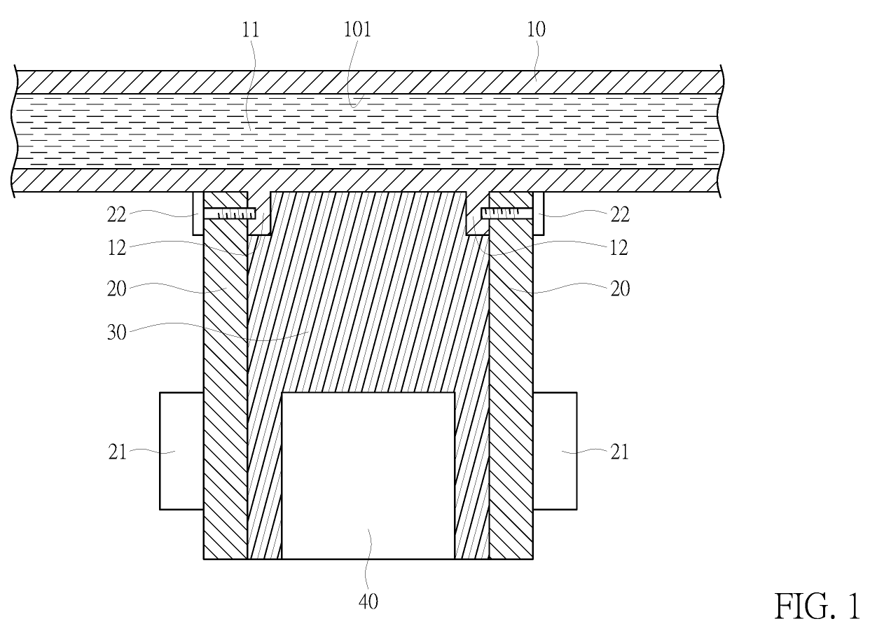

With reference to FIG. 1, a first embodiment of a liquid cooling structure in accordance with the present invention is shown, is mounted inside an electronic device, and is configured to wrap a heat-generating component 40 inside the electronic device. Specifically, the electronic device may be a power supply and the heat-generating component 40 may be a transformer module of the power supply. However, it is not limited thereto, the heat-generating component 40 may also be any other electronic component with high heat generation within other electronic devices.

The liquid cooling structure comprises a cooling plate 10 and a circuit board 20. The cooling plate 10 has a flow channel 101 formed in the cooling plate 10 for cooling liquid 11 to flow through the cooling plate 10. The circuit board 20 is a circuit substrate such as a printed circuit board (PCB), an aluminum substrate, a copper substrate or the like. The circuit board 20 is mounted with at least one additional heat-generating component 21, such as power semiconductors, transistors and the like. The cooling plate 10 and the circuit board 20 are arranged around the heat-generating component 40, thereby wrapping the heat-generating component 40 in a space surrounded by the cooling plate 10 and the circuit board 20. The space surrounded by the cooling plate 10 and the circuit board 20 is filled with a first thermal conductive medium 30. The first thermal conductive medium 30 is in direct contact with the cooling plate 10 and is also in direct contact with the circuit board 20. Thus, heat generated by the heat-generating component 40 and said at least one additional heat-generating component 21 is able to be quickly conducted through the first thermal conductive medium 30 to the cooling plate 10 or through the circuit board 20, which is in direct contact with the cooling plate 10, to the cooling plate 10, and then be dissipated via the cooling liquid 11 inside the cooling plate 10.

As shown in FIG. 1, in a specific implementation shown in the first preferred embodiment of the present invention, said at least one additional heat-generating component 21 is mounted on an outer surface of the circuit board 20. An inner surface of the circuit board 20 faces toward the heat-generating component 40 and is in direct contact with the first thermal conductive medium 30. The cooling plate 10 has at least one fastening protrusion 12 formed on an outer sidewall of the cooling plate 10. Multiple fasteners 22 are mounted through the circuit board 20 and are fastened to the at least one fastening protrusion 12. Accordingly, the circuit board 20 and the cooling plate 10 are fixed together and the heat generated by the heat-generating component 40 and said at least one additional heat-generating component 21 is able to be conducted through the circuit board 20 and the at least one fastening protrusion 12 of the cooling plate 10 and then be dissipated via the cooling liquid 11 inside the cooling plate 10.

Specifically, the cooling plate 10 has two sidewalls to form the flow channel 101, and the circuit board 20 has two substrates fastened to one of the sidewalls of the cooling plate 10. The cooling plate 10 and the substrates of the circuit board 20 form the space for accommodating the heat-generating component 40. Each of the substrates of the circuit board 20 has an inner surface and an outer surface. Said at least one second additional heat-generating component 21 is mounted on at least one of the outer and inner surfaces of the substrates.

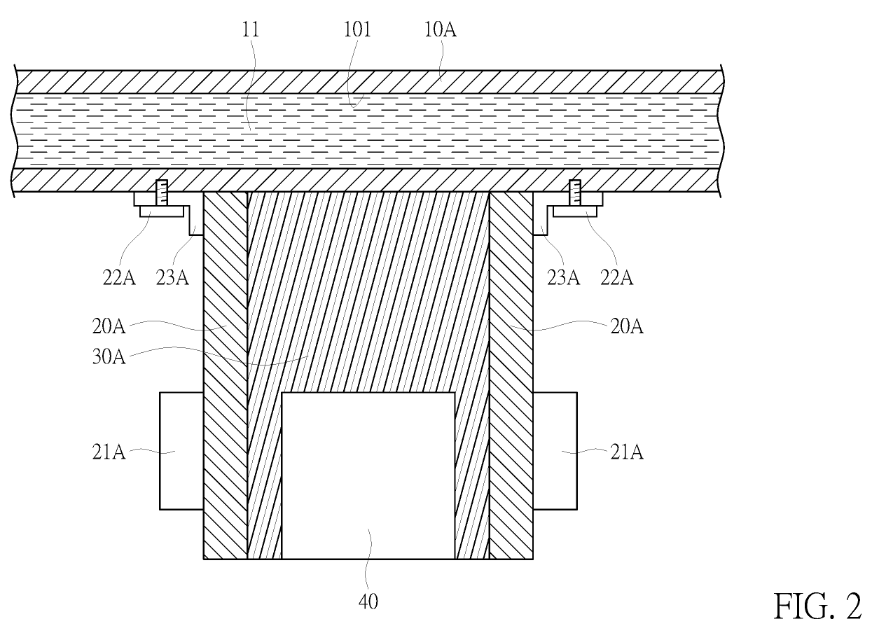

With reference to FIG. 2, a second preferred embodiment of the liquid cooling structure in accordance with the present invention is shown. Similar to the first preferred embodiment of the liquid cooling structure as described, said at least one additional heat-generating component 21A is mounted on the outer surface of the circuit board 20A, and the inner surface of the circuit board 20A faces toward the heat-generating component 40 and is in direct contact with the first thermal conductive medium 30A. The difference between the second preferred embodiment and the first embodiment is that, in the second preferred embodiment, the cooling plate 10A and the circuit board 20A are connected with each other through multiple connectors 23A. A portion of each one of the connectors 23A is securely connected to the cooling plate 10A and another portion of each one of the connectors 23A is securely connected to the circuit board 20A. Thus, the circuit board 20A and the cooling plate 10A are fixed together.

In a specific implementation shown in the second preferred embodiment of the present invention, each one of the fasteners 22A is mounted through a corresponding one of the connectors 23A and is fastened to the cooling plate 10, such that the connectors 23A is securely connected to the cooling plate 10A. Furthermore, each one of the connectors 23A is L-shaped. However, it is not limited thereto, the shape of each one of the connectors 23A can be selected according to relative positions of the cooling plates 10A and the circuit board 20A.

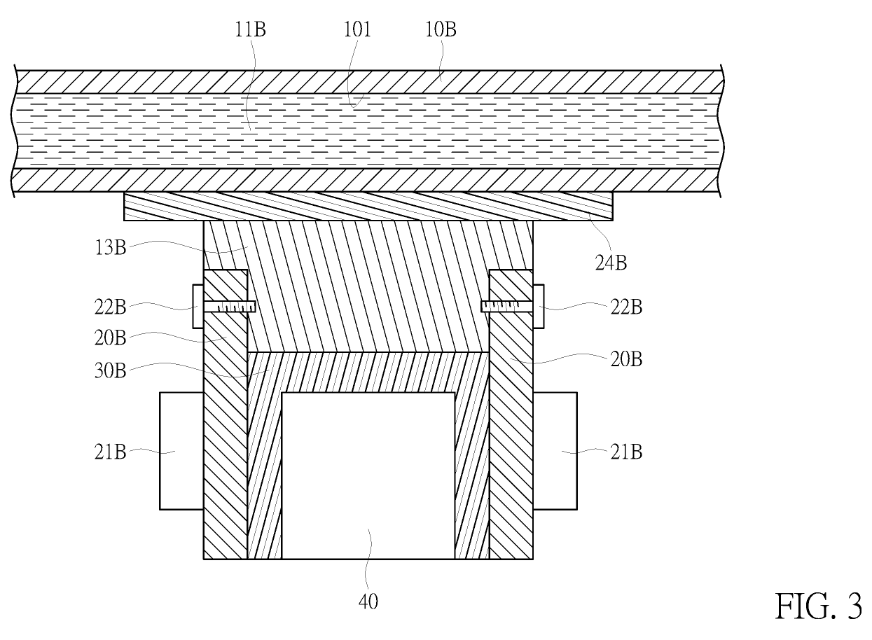

With reference to FIG. 3, a third preferred embodiment of the liquid cooling structure in accordance with the present invention is shown. Similar to the first preferred embodiment of the liquid cooling structure as described, said additional at least one heat-generating components 21B is mounted on the outer surface of the circuit board 20B, and the inner surface of the circuit board 20B faces toward the heat-generating component 40 and is in direct contact with the first thermal conductive medium 30B. The difference between the third preferred embodiment of the liquid cooling structure and the first preferred embodiment is that, in the third preferred embodiment, a thermal block 13B is further mounted on the outer sidewall of the cooling plate 10B. The space for accommodating the heat-generating component 40 is surrounded by the cooling plate 10B, with a portion on which the thermal block 13B is mounted, and the circuit board 20B, such that the cooling plate 10B is in direct contact with the first thermal conductive medium 30B by using the thermal block 13B. Thus, the heat generated by the heat-generating component 40 and said addition devices 21B to be heat dissipated is directly conducted to the first thermal conductive medium 30B first, and then to the cooling plate 10B via the thermal block 13B or to the cooling plate 10B via a contact area of the circuit board 20B and the thermal block 13B, so as to dissipate the heat via the cooling liquid 11B inside the cooling plate 10B.

Preferably, the thermal block 13B is attached to the cooling plate 10B with a second thermal conductive medium 24B. The fasteners 22B are mounted through the circuit board 20B and are fastened to the thermal block 13B. Specifically, the thermal block 13B may be made of metals with high thermal conductivity, such as aluminum, aluminum alloy, copper, copper alloy, or the like.

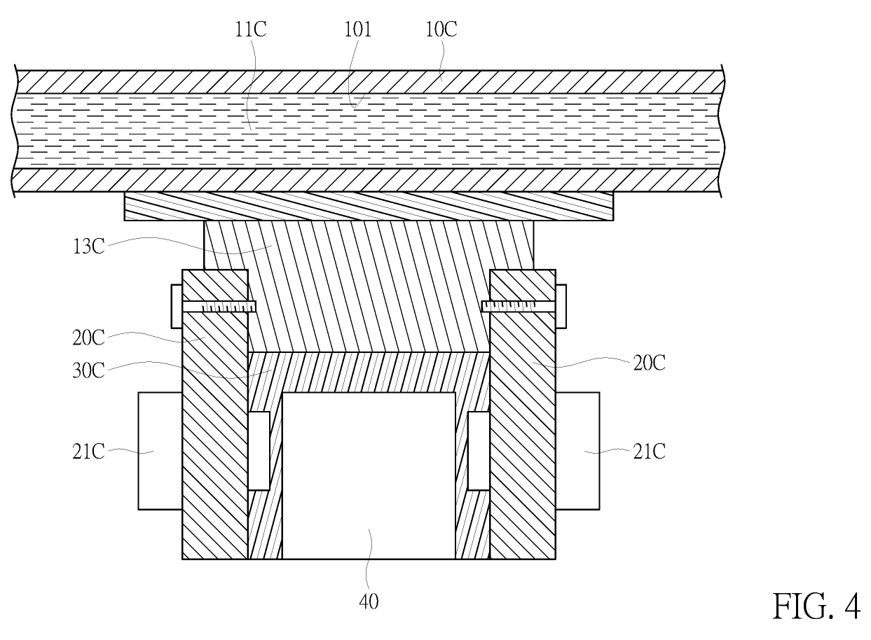

With reference to FIG. 4, a fourth preferred embodiment of the liquid cooling structure in accordance with the present invention is shown and is similar to the third preferred embodiment of the liquid cooling structure. The difference between the fourth preferred embodiment of the liquid cooling structure and the third preferred embodiment is that, in the fourth preferred embodiment, said addition devices 21C to be heat dissipated are mounted on the outer surface and the inner surface of the circuit board 20C, and the at least one additional heat-generating component 21C, which is mounted on the inner surface of the circuit board 20C, are in direct contact with the first thermal conductive medium 30C. Thus, the heat generated by the heat-generating component 40 and said additional at least one heat-generating component 21C, which is mounted on the outer surface and the inner surface of the circuit board 20C is able to be directly conducted to the first thermal conductive medium 30C first, and then to the cooling plate 10C via the thermal block 13C or to the cooling plate 10C via the contact area of the circuit board 20C and the thermal block 13C, so as to dissipate the heat via the cooling liquid 11C inside the cooling plate 10C.

The liquid cooling structure as described has the following advantages. In the liquid cooling structure, a heat sink for wrapping the heat-generating component 40 is omitted, and the first thermal conductive medium 30, 30A, 30B, 30C is in direct contact with the heat-generating component 40, the circuit board 20, 20A, 20B, 20C and the cooling plate 10, 10A, 10B, 10C. Therefore, in addition to simplifying a structure and assembling processes of the liquid cooling structure, thermal resistances in the liquid cooling structure can be reduced and thermal conductivity of the liquid cooling structure can be improved. A minimum thermal resistance between the heat-generating component 40 and the cooling plate 10, 10A, 10B, 10C is consisting of the first thermal conductive medium 30, 30A, 30B, 30C. Moreover, a size of the liquid cooling structure and a size of the electronic device having the liquid cooling structure can also be further reduced.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A liquid cooling structure configured to wrap a heat-generating component and comprising a cooling plate and a circuit board; the cooling plate and the circuit board arranged to form a space for accommodating the heat-generating component; the space filled with a first thermal conductive medium; and the first thermal conductive medium being in direct contact with the cooling plate and being in direct contact with the circuit board.

2. The liquid cooling structure as claimed in claim 1, further comprising a flow channel formed in the cooling plate for cooling liquid to flow through.

3. The liquid cooling structure as claimed in claim 1, wherein the circuit board is mounted with at least one additional heat-generating component.

4. The liquid cooling structure as claimed in claim 3, wherein the at least one additional heat-generating component is mounted on an outer surface of the circuit board.

5. The liquid cooling structure as claimed in claim 3, wherein the circuit board is mounted with a plurality of said at least one additional heat-generating components, and the additional heat-generating components are respectively mounted on an outer surface and an inner surface of the circuit board.

6. The liquid cooling structure as claimed in claim 1, wherein the cooling plate has at least one fastening protrusion formed on an outer sidewall of the cooling plate.

7. The liquid cooling structure as claimed in claim 6, wherein the liquid cooling structure further comprises a fastener fastened, passing through the circuit board, to a corresponding one of the at least one fastening protrusion.

8. The liquid cooling structure as claimed in claim 1, further comprising a connector having a portion fastened to the cooling plate and another portion fastened to the circuit board, wherein the cooling plate and the circuit board are connected with each other through the connector.

9. The liquid cooling structure as claimed in claim 8, further comprising a fastener fastened, passing through the connector, to the cooling plate.

10. The liquid cooling structure as claimed in claim 1, further comprising a thermal block mounted on an outer sidewall of the cooling plate, wherein the portion of the cooling plate with the thermal block, together with the circuit board, forms the space for accommodating the heat-generating component, so that the cooling plate is in contact with the first thermal conductive medium through the thermal block.

11. The liquid cooling structure as claimed in claim 10, wherein the thermal block is attached to the cooling plate through a second thermal conductive medium.

12. An electronic device comprising:
a first heat-generating component; and
a liquid cooling structure wrapping the first heat-generating component, wherein the liquid cooling structure comprises:
a cooling plate having two sidewalls to form a flow channel for cooling liquid to flow through; and
a circuit board having two substrates fastened to one of the sidewalls of the cooling plate,
wherein the cooling plate and the substrates form a space for accommodating the first heat-generating component, and the space is filled with a first thermal conductive medium, and
wherein the first thermal conductive medium is in direct contact with the cooling plate and is in direct contact with the circuit board.

13. The electronic device as claimed in claim 12, wherein each of the substrates has an inner surface and an outer surface, and the electronic device further comprises at least one second heat-generating component mounted on at least one of the outer and inner surfaces of the substrates.

14. The electronic device as claimed in claim 12, wherein the cooling plate has a plurality of fastening protrusions formed on an outer surface of one of the sidewalls of the cooling plate, and the liquid cooling structure further comprises a plurality of fasteners respectively fastened to the fastening protrusions through the substrates.

15. The electronic device as claimed in claim 12, wherein the liquid cooling structure further comprises:
a plurality of connectors, each of the connectors having a portion fastened to the cooling plate and another portion fastened to the circuit board; and
a plurality of fasteners respectively fastened to an outer surface of one of the sidewalls of the cooling plate through the connectors.

16. The electronic device as claimed in claim 12, wherein a minimum thermal resistance between the first heat-generating component and the cooling plate is consisting of the first thermal conductive medium.

17. An electronic device comprising:
a first heat-generating component; and
a liquid cooling structure wrapping the first heat-generating component, wherein the liquid cooling structure comprises:
a cooling plate having two sidewalls to form a flow channel for cooling liquid to flow through;
a circuit board having two substrates fastened to one of the sidewalls of the cooling plate; and
a thermal block mounted on one of the sidewalls, to which the two substrates of the circuit board is fastened, of the cooling plate;
wherein the thermal block and the substrates form a space for accommodating the first heat-generating component, and the space is filled with a first thermal conductive medium, and
wherein the first thermal conductive medium is thermal contact with the cooling plate through the thermal block and is in direct contact with the circuit board.

18. The electronic device as claimed in claim 17, wherein the thermal block is attached to the cooling plate through a second thermal conductive medium.

19. The electronic device as claimed in claim 18, wherein a minimum thermal resistance between the first heat-generating component and the circuit board is consisting of the first thermal conductive medium.

20. The electronic device as claimed in claim 17, wherein the thermal block is in direct contact with only a portion of an inner surface of each of the substrates of the circuit board.
